(19) United States
(12) Patent Application Publication
(10) Pub. No.: US 2024/0072152 A1
(43) Pub. Date: Feb. 29, 2024

(54) METHOD OF MANUFACTURING SEMICONDUCTOR DEVICE

(71) Applicant: FUJI ELECTRIC CO., LTD., Kawasaki-shi (JP)

(72) Inventors: Naoki KUNESHITA, Matsumoto-city (JP); Masayuki MOMOSE, Matsumoto-city (JP); Ryutaro HAMASAKI, Matsumoto-city (JP)

(73) Assignee: FUJI ELECTRIC CO., LTD., Kawasaki-shi (JP)

(21) Appl. No.: 18/214,044

(22) Filed: Jun. 26, 2023

(30) Foreign Application Priority Data
Aug. 23, 2022 (JP) 2022-132513

(51) Int. Cl. H01L 29/66; H01L 29/10; H01L 29/739

(52) U.S. Cl. CPC H01L 29/66348; H01L 29/1095; H01L 29/7397

(57) ABSTRACT

A method of manufacturing a semiconductor device includes: forming a first trench from an upper surface side of a semiconductor substrate; burying the first trench with an insulated gate electrode structure; forming a base region at an upper part of the semiconductor substrate so as to be in contact with the first trench; forming a first main electrode region at an upper part of the base region so as to be in contact with the first trench; forming a second trench by removing a part of the first main electrode region; implanting first impurity ions entirely into a side wall surface of the second trench from a diagonally upper side; implanting second impurity ions into a bottom surface of the second trench to form a contact region at a bottom of the second trench; and forming a second main electrode region on a bottom surface side of the semiconductor substrate.

### CROSS-REFERENCE TO RELATED APPLICATION

This application claims benefit of priority under 35 USC 119 based on Japanese Patent Application No. 2022-132513 filed on Aug. 23, 2022, the entire contents of which are incorporated by reference herein.

### BACKGROUND OF THE INVENTION

### 1. Field of the Invention

The present invention relates to a method of manufacturing a semiconductor device.

### 2. Description of the Related Art

Conventional semiconductor devices such as insulated gate bipolar transistors (IGBTs) having a trench gate structure have a problem with faults in a reduction in latch-up tolerance because of an increase in resistance in association with a minimization of a contact in a mesa part between a gate and a trench, and are thus required to have a low resistance in the contact. To achieve the low resistance in the contact, a contact trench is provided in the mesa part between the gate and the trench, so as to increase the area of the contact not only on the bottom surface but also on the side wall surface of the contact trench.

A contact trench is typically formed such that p-type impurity ions such as boron (B) are implanted into the bottom surface of the contact trench to form a contact region having a higher impurity concentration than a base region of p-type so as to be in contact with the base region to decrease a contact resistance.

JP 5034151 B2 discloses a method of manufacturing a power MOSFET, including a step of implanting p-type impurity ions into a contact trench in a direction perpendicular to the contact trench to form a p⁺-type region at a bottom of the contact trench, and a step of implanting n-type impurity ions into an upper part of a side wall surface of the contact trench from the diagonally upper side so as to form a source region of n⁺-type at the upper part of the side wall surface of the contact trench.

JP 2013-172034 A discloses a method of manufacturing a semiconductor device including: a step of forming two trenches extending in a first direction and having a first side surface, a second side surface and a bottom surface in a semiconductor substrate with the second side surfaces facing each other; a step of forming a first impurity diffusion region by implanting ions of a first impurity dopant from an obliquely upward direction into the semiconductor substrate on the second side surface side of the other trench; and a step of forming a second impurity diffusion region joining to the first impurity diffusion region by implanting the first impurity dopant into the semiconductor substrate on the second side surface from the obliquely upward direction to form a third impurity diffusion region by integrating the second impurity diffusion region.

As described above, the p-type impurity ions are implanted in the direction perpendicular to the bottom surface of the contact trench not only into the bottom surface but also into the side wall surface of the contact trench when the contact trench has a tapered shape. The p-type impurity ions collide against interstitial atoms in a semiconductor substrate and are diffused during the ion implantation, and are thus inevitably distributed in the lateral direction. The p-type impurity ions, if reaching a region adjacent to the gate trench, may cause a fluctuation (an increase) or a variation in gate threshold voltage. The mesa part between the gate and the trench thus needs to have a particular width in order to stabilize the electrical properties, which avoids or limits the minimization of the semiconductor device.

### SUMMARY OF THE INVENTION

In view of the foregoing problems, the present invention provides a method of manufacturing a semiconductor device with a configuration capable of suppressing a fluctuation or a variation in gate threshold voltage during an implantation of ions into a contact trench so as to achieve a minimization of the semiconductor device.

An aspect of the present invention inheres in a method of manufacturing a semiconductor device including: forming a first trench from an upper surface side of a semiconductor substrate of a first conductivity-type; burying the first trench with an insulated gate electrode structure; forming a base region of a second conductivity-type at an upper part of the semiconductor substrate so as to be in contact with the first trench; forming a first main electrode region of the first conductivity-type at an upper part of the base region so as to be in contact with the first trench; forming a second trench by removing a part of the first main electrode region; implanting first impurity ions of the first conductivity-type entirely into a side wall surface of the second trench from a diagonally upper side; implanting second impurity ions of the second conductivity-type into a bottom surface of the second trench so as to form a contact region of the second conductivity-type at a bottom of the second trench; and forming a second main electrode region of the second conductivity-type on a bottom surface side of the semiconductor substrate.

### BRIEF DESCRIPTION OF THE DRAWINGS

FIG. 1 is a plan view illustrating an example of a semiconductor device according to a first embodiment;

FIG. 2 is a cross-sectional view as viewed from direction A-A in FIG. 1;

FIG. 3 is a cross-sectional enlarged view illustrating region A in FIG. 2;

FIG. 4 is a cross-sectional process view illustrating an example of a method of manufacturing the semiconductor device according to the first embodiment;

FIG. 5 is a cross-sectional process view continued from FIG. 4, illustrating the example of the method of manufacturing the semiconductor device according to the first embodiment;

FIG. 6 is a cross-sectional process view continued from FIG. 5, illustrating the example of the method of manufacturing the semiconductor device according to the first embodiment;

FIG. 7 is a cross-sectional process view continued from FIG. 6, illustrating the example of the method of manufacturing the semiconductor device according to the first embodiment;

FIG. 8 is a cross-sectional process view continued from FIG. 7, illustrating the example of the method of manufacturing the semiconductor device according to the first embodiment;

FIG. 9 is a cross-sectional process view continued from FIG. 8, illustrating the example of the method of manufacturing the semiconductor device according to the first embodiment;

FIG. 10 is a cross-sectional process view continued from FIG. 9, illustrating the example of the method of manufacturing the semiconductor device according to the first embodiment;

FIG. 11 is a cross-sectional process view continued from FIG. 10, illustrating the example of the method of manufacturing the semiconductor device according to the first embodiment;

FIG. 12 is a cross-sectional process view continued from FIG. 11, illustrating the example of the method of manufacturing the semiconductor device according to the first embodiment;

FIG. 13 is a cross-sectional process view continued from FIG. 12, illustrating the example of the method of manufacturing the semiconductor device according to the first embodiment;

FIG. 14 is a cross-sectional process view illustrating a method of manufacturing a semiconductor device of a comparative example;

FIG. 15 is a graph showing a relation between a dose, an acceleration energy, and a lateral-direction diffusion distance of diagonally-implanted ions;

FIG. 16 is a graph showing a relation between the dose, a tilt angle, and the lateral-direction diffusion distance of the diagonally-implanted ions;

FIG. 17 is a cross-sectional process view illustrating an example of a method of manufacturing a semiconductor device according to a second embodiment;

FIG. 18 is a cross-sectional process view illustrating an example of a method of manufacturing a semiconductor device according to a third embodiment;

FIG. 19 is a cross-sectional process view illustrating an example of a method of manufacturing a semiconductor device according to a fourth embodiment; and

FIG. 20 is a cross-sectional process view continued from FIG. 19, illustrating the example of the method of manufacturing the semiconductor device according to the fourth embodiment.

### DETAILED DESCRIPTION

With reference to the drawings, first to fourth embodiments of the present invention will be described below.

In the drawings, the same or similar elements are indicated by the same or similar reference numerals. The drawings are schematic, and it should be noted that the relationship between thickness and planer dimensions, the thickness proportion of each layer, and the like are different from real ones. Accordingly, specific thicknesses or dimensions should be determined with reference to the following description. Moreover, in some drawings, portions are illustrated with different dimensional relationships and proportions.

In the following description, a “first main electrode region” and a “second main electrode region” are a main electrode region of a semiconductor element, in which a main current flows in or out. The first main electrode region is assigned to a semiconductor region which is an emitter region or a collector region in an insulated-gate bipolar transistor (IGBT). The first main electrode region is assigned to a semiconductor region which is a source region or a drain region in a field-effect transistor (FET) or a static induction transistor (SIT). The first main electrode region is assigned to a semiconductor region which is an anode region or a cathode region in a static induction (SI) thyristor or a gate turn-off (GTO) thyristor. The second main electrode region is assigned to a semiconductor region which is not assigned as the first main electrode region and will be the emitter region or the collector region in the IGBT, the source region or the drain region in the FET or the SIT, and the anode region or the cathode region in the SI thyristor or the GTO thyristor. That is, when the first main electrode region is the source region, the second main electrode region means the drain region. When the first main electrode region is the emitter region, the second main electrode region means the collector region. When the first main electrode region is the anode region, the second main electrode region means the cathode region. A “main electrode region” is described in the specification, the main electrode region comprehensively means any one of the first main electrode region and the second main electrode region.

Further, definitions of directions such as an up-and-down direction in the following description are merely definitions for convenience of understanding, and are not intended to limit the technical ideas of the present invention. For example, as a matter of course, when the subject is observed while being rotated by 90°, the subject is understood by converting the up-and-down direction into the right-and-left direction. When the subject is observed while being rotated by 180°, the subject is understood by inverting the up-and-down direction.

Further, in the following description, there is exemplified a case where a first conductivity-type is an n-type and a second conductivity-type is a p-type. However, the relationship of the conductivity types may be inverted to set the first conductivity-type to the p-type and the second conductivity-type to the n-type. Further, a semiconductor region denoted by the symbol “n” or “p” attached with “+” indicates that such semiconductor region has a relatively high impurity concentration or a relatively low specific resistance as compared to a semiconductor region denoted by the symbol “n” or “p” without “+”. A semiconductor region denoted by the symbol “n” or “p” attached with “−” indicates that such semiconductor region has a relatively low impurity concentration or a relatively high specific resistance as compared to a semiconductor region denoted by the symbol “n” or “p” without “−”. However, even when the semiconductor regions are denoted by the same reference symbols “n” and “n”, it is not indicated that the semiconductor regions have exactly the same impurity concentration or the same specific resistance.

### First Embodiment

<Structure of Semiconductor Device>

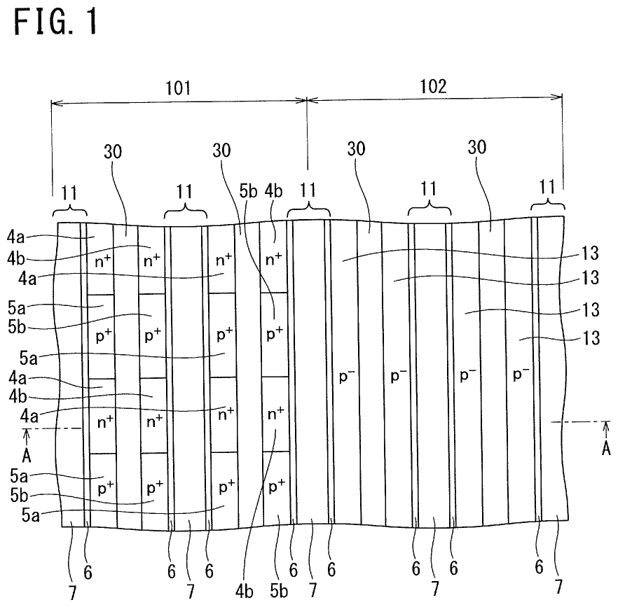

FIG. 1 is a plan view illustrating a part of an active region of a semiconductor device according to a first embodiment as viewed from the top surface (the front surface) side. As illustrated in FIG. 1, the semiconductor device according to the first embodiment includes a transistor part 101 including a transistor element such as an IGBT, and a diode part 102 including a diode element, the transistor part 101 and the diode part 102 integrated on the same semiconductor chip. The semiconductor device according to the first embodiment is a reverse-conducting IGBT (a RC-IGBT), for example, in which an IGBT that is the transistor part 101 and a freewheeling diode (FWD) that is the diode part 102 connected in antiparallel to the IGBT are integrated on the same semiconductor chip. A plurality of transistor parts 101 and diode parts 102 may be arranged alternately in the right-left direction in FIG. 1.

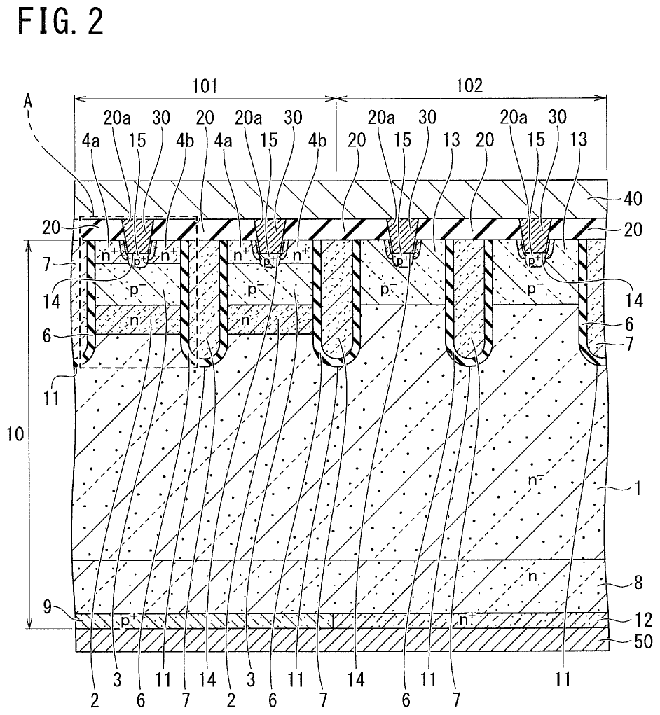

FIG. 2 is a cross-sectional view taken along line A-A in FIG. 1 cross-sectioned across the transistor part 101 and the diode part 102. As illustrated in FIG. 2, the semiconductor device according to the first embodiment includes a semiconductor substrate 10. The semiconductor substrate 10 is a silicon (Si) substrate, for example. The semiconductor substrate 10 is not limited to the Si substrate, and may be any other semiconductor substrate of a semiconductor (a wide band-gap semiconductor) having a wider band gap than Si, such as silicon carbide (SiC), gallium nitride (GaN), gallium oxide (Ga₂O₃), diamond (C), or aluminum nitride (AlN).

The semiconductor substrate 10 includes a drift layer 1 of a first conductivity-type (n⁻-type). An accumulation layer 2 of n-type having a higher impurity concentration than the drift layer 1 is deposited on the top surface side of the drift layer 1 in the transistor part 101. The bottom surface of the accumulation layer 2 is in contact with the top surface of the drift layer 1. The presence of the accumulation layer 2 can enhance the effect of promoting a carrier injection enhancement effect (an IE effect) so as to decrease an ON-voltage.

The transistor part 101 includes a base region 3 of a second conductivity-type (p⁻-type) deposited on the top surface side of the accumulation layer 2. The bottom surface of the base region 3 is in contact with the top surface of the accumulation layer 2. First main electrode regions (emitter regions) 4a and 4b of n⁺-type are deposited on the top surface side of the base region 3. The respective bottom surfaces of the emitter regions 4a and 4b are in contact with the top surface of the base region 3. The emitter regions 4a and 4b each have a higher impurity concentration than the drift layer 1 and the accumulation layer 2.

The top surface side of the drift layer 1 in the diode part 102 is not provided with any accumulation layer as provided in the transistor part 101. An accumulation layer of n-type having a higher impurity concentration than the drift layer 1 may also be provided on the top surface side of the drift layer 1 in the diode part 102. An anode region 13 of p⁻-type is deposited on the top surface side of the drift layer 1 in the diode part 102. The bottom surface of the anode region 13 is in contact with the top surface of the drift layer 1. The anode region 13 is deposited to have a top surface located at the same level as the top surface of the semiconductor substrate 10. The anode region 13 may be provided to have the same depth and the same impurity concentration as the base region 3 in the transistor part 101.

A plurality of trenches (gate trenches) 11 are provided separately from each other extending from the top surface of the semiconductor substrate 10 in the depth direction that is perpendicular to the top surface of the semiconductor substrate 10 in each of the transistor part 101 and the diode part 102. The respective gate trenches 11 in the transistor part 101 penetrate the respective emitter regions 4a and 4b, the base region 3, and the accumulation layer 2 so as to reach the drift layer 1. The respective side surfaces of the emitter regions 4a and 4b, the base region 3, and the accumulation layer 2 are in contact with the side surfaces (the side wall surfaces) of the respective gate trenches 11. The respective gate trenches 11 in the diode part 102 penetrate the anode region 13 so as to reach the drift layer 1. The side surface of the anode region 13 is in contact with the side surfaces of the respective gate trenches 11.

The region between the respective gate trenches 11 next to each other is provided with a mesa part implemented by the upper part of the semiconductor substrate 10 in the parallel direction of the respective gate trenches 11. The mesa part is a region of the semiconductor substrate 10 interposed between the respective gate trenches 11 next to each other, and is located at a higher position than the deepest part of the gate trenches 11. The upper part of the drift layer 1, the accumulation layer 2, the base region 3, and the emitter regions 4a and 4b are provided in the mesa part in the transistor part 101. The upper part of the drift layer 1 and the anode region 13 are provided in the mesa part in the diode part 102.

A gate insulating film 6 is provided to cover the bottom surface and the side surface of the respective gate trenches 11. The gate insulating film 6 as used herein can be a single film of a silicon dioxide film (a SiO₂ film), a silicon oxynitride (SiON) film, a strontium oxide (SrO) film, a silicon nitride (Si₃N₄) film, an aluminum oxide (Al₂O₃) film, a magnesium oxide (MgO) film, an yttrium oxide (Y₂O₃) film, a hafnium oxide (HfO₂) film, a zirconium oxide (ZrO₂) film, a tantalum oxide (Ta₂O₅) film, or a bismuth oxide (Bi₂O₃) film, or a composite film including some of the above films stacked on one another.

A gate electrode 7 is buried inside the respective gate trenches 11 with the gate insulating film 6 interposed. The gate insulating film 6 and the gate electrode 7 implement an insulated gate electrode structure (6, 7). The gate electrode 7 as used herein can be made of a polysilicon film (a doped polysilicon film) heavily doped with impurity ions such as phosphorus (P) or boron (B), for example.

A part of the plural insulated gate electrode structures (6, 7) in the transistor part 101 serves as a gate trench part connected to a gate runner, and the other may serve as a dummy trench part not connected to the gate runner. The respective insulated gate electrode structures (6, 7) in the diode part 102 may each serve as a dummy trench part not connected to the gate runner.

As illustrated in FIG. 1, the plural gate trenches 11 each have a straight (stripe-shaped) part extending parallel to each other in one direction (the upper-lower direction in FIG. 1) in the planar pattern. The anode region 13 in the diode part 102 has a straight (stripe-shaped) part extending parallel to the extending direction of the respective gate trenches 11.

A contact region 5a of p⁺-type and the emitter region 4a of n⁺-type are alternately and repeatedly arranged parallel to the extending direction (the longitudinal direction) of the respective gate trenches 11 in the transistor 101, and a contact region 5b of p⁺-type and the emitter region 4b of n⁺-type are alternately and repeatedly arranged in the same matter. The contact region 5a is in contact with the emitter region 4a. The contact region 5b is in contact with the emitter region 4b. The contact regions 5a and 5b are deposited on the top surface side of the base region 3 illustrated in FIG. 2. The bottom surfaces of the respective contact regions 5a and 5b are in contact with the top surface of the base region 3. The respective contact regions 5a and 5b have a higher impurity concentration than the base region 3.

As illustrated in FIG. 2, an interlayer insulating film 20 is deposited on the top surfaces of the semiconductor substrate 10 and the respective insulated gate electrode structures (6, 7). The interlayer insulating film 20 is a single film of a silicon oxide film (a SiO₂ film) without containing phosphorus (P) or boron (B) which is referred to as a non-doped silicate glass (NSG) film, a phosphosilicate glass film (a PSG film), a borosilicate glass film (a BSG film), a borophosphosilicate glass film (a BPSG film), a silicon nitride (Si₃N₄) film, or a high temperature oxide film (a HTO film), or a stacked layer of the above films stacked on one another.

The interlayer insulating film 20 located on the mesa part of the semiconductor substrate 10 between the respective gate trenches 11 is provided with contact holes 20a penetrating the interlayer insulating film 20. The mesa part of the semiconductor substrate 10 between the respective gate trenches 11 is provided with trenches (contact trenches) 14 integrated with the contact holes 20a. The respective contact trenches 14 are dug from the top surface of the mesa part in the depth direction perpendicular to the top surface of the mesa part.

A contact plug 30 made from tungsten (W), for example, is buried in the respective contact trenches 14 and the respective contact holes 20a with a barrier metal film such as a titanium silicide (TiSi₂) film and a titanium nitride (TiN) film interposed (not illustrated).

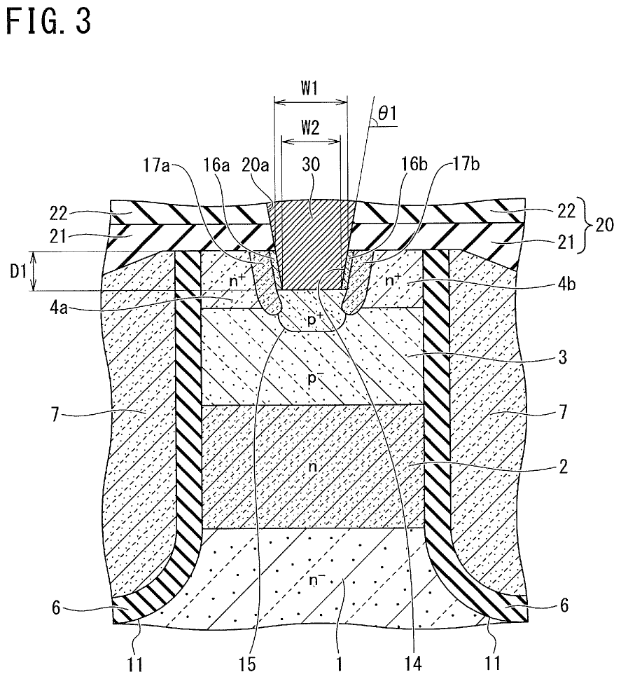

FIG. 3 is an enlarged view illustrating region A in FIG. 2 including the circumference of the contact trench 14 in the transistor part 101. The circumference of the other contact trenches 14 illustrated in FIG. 2 each have the same structure as the enlarged view illustrated in FIG. 3. As illustrated in FIG. 3, the interlayer insulating film 20 includes a first insulating film 21 of a HTO film or the like, and a second insulating film 22 of a BPS G film or the like deposited on the top surface of the first insulating film 21. The respective emitter regions 4a and 4b have a thickness in a range of about 0.3 micrometers or greater and less than 0.6 micrometers, for example. A gap between the respective gate trenches 11 next to each other is in a range of about 0.5 micrometers or greater and 1.0 micrometers or smaller.

As illustrated in FIG. 3, the contact trench 14 is provided at the upper part of the emitter regions 4a and 4b located at the mesa part between the gate trenches 11 next to each other. The contact trench 14 has a tapered shape (a regular tapered shape) having a width gradually decreasing toward the bottom surface from the opening at the upper end. A width (an opening width) W1 of the opening of the contact trench 14 is wider than a width W2 of the bottom surface of the contact trench 14. The respective side walls of the contact trench 14 may be orthogonal to the top surface of the emitter region 4 instead.

The opening width W1 of the contact trench 14 is in a range of about greater than 0.1 micrometers and 0.5 micrometers or smaller, for example. The width W2 of the bottom surface of the contact trench 14 is in a range of about 0.1 micrometers or greater and smaller than 0.5 micrometers, for example. A tapered angle θ1 of the respective side walls of the contact trench 14 is in a range of 80 degrees or greater and less than 90 degrees, for example. A depth D1 between the opening to the bottom surface of the contact trench 14 is in a range of about 0.2 micrometers or greater and 1.0 micrometers or smaller, for example.

A contact region 15 of p⁺-type having a higher impurity concentration than the base region 3 is deposited under the bottom surface of the contact trench 14. The bottom surface of the contact region 15 is located at a lower position than the respective bottom surfaces of the emitter regions 4a and 4b. The contact region 15 is in contact with the base region 3. The maximum width of the contact region 15 in the lateral direction is greater than the width W2 of the bottom of the contact trench 14. The contact region 15 is in ohmic contact with the contact plug 30. The presence of the contact region 15 can decrease a contact resistance between the contact region 15 and the contact plug 30.

The end parts of the emitter regions 4a and 4b in contact with the respective side wall surfaces of the contact trench 14 are provided with side-wall implantation regions 16a and 16b of n⁺-type and suppression regions 17a and 17b of n⁺-type. The side surfaces of the side-wall implantation regions 16a and 16b are in contact with the side wall surfaces of the contact trench 14. The upper ends of the side-wall implantation regions 16a and 16b are in contact with the first insulating film 21. The lower ends of the side-wall implantation regions 16a and 16b are in contact with the contact region 15. The side-wall implantation regions 16a and 16b have a width in a range of about 0.05 micrometers or greater and 0.2 micrometers or smaller, for example.

The side-wall implantation regions 16a and 16b are the n-type regions formed such that p-type impurity ions are implanted into the emitter regions 4a and 4b through the side wall surfaces of the contact trench 14 upon the implantation of the p-type impurity ions for forming the contact region 15 when the contact trench 14 has a tapered shape. While the side-wall implantation regions 16a and 16b have the configuration in which n-type impurity ions are compensated (canceled out) by the implanted p-type impurity ions, and thus have a lower impurity concentration than the emitter regions 4a and 4b, the side-wall implantation regions 16a and 16b are in ohmic contact with the contact plug 30 because the impurity concentration of the emitter regions 4a and 4b is sufficiently high.

The suppression regions 17a and 17b are provided separately from the contact trench 14 and are in contact with the side surfaces of the side-wall implantation regions 16a and 16b opposite to the side in contact with the side wall surfaces of the contact trench 14. The upper ends of the suppression regions 17a and 17b are in contact with the first insulating film 21. The lower ends of the suppression regions 17a and 17b are in contact with the contact region 15. The lower ends of the suppression regions 17a and 17b extend to reach the parts of the contact region 15 under the bottom surface of the contact trench 14 so as to surround the circumference of the corners defined by the bottom surface and the side wall surfaces of the contact trench 14.

The suppression regions 17a and 17b are the n-type regions formed such that n-type impurity ions are implanted into the emitter regions 4a and 4b from the diagonally upper side through the side wall surfaces of the contact trench 14. The suppression regions 17a and 17b compensate (cancel out) the p-type impurity ions implanted into the side-wall implantation regions 16a and 16b and thus have a higher impurity concentration than the side-wall implantation regions 16a and 16b. The suppression regions 17a and 17b on the side toward the respective emitter regions 4a and 4b may have a higher impurity concentration than the emitter regions 4a and 4b. The suppression regions 17a and 17b have a function of suppressing a diffusion of the p-type impurity ions in the lateral direction due to the compensation of the p-type impurity ions implanted into the side-wall implantation regions 16a and 16b.

The bottom surface of the contact plug 30 buried in the contact trench 14 is in ohmic contact with the contact region 15. The side surfaces of the contact plug 30 are in ohmic contact with the side-wall implantation regions 16a and 16b. The contact plug 30 in the diode part 102 illustrated in FIG. 2 is in ohmic contact with the contact region 15 provided at the upper part of the anode region 13.

As illustrated in FIG. 2, a front-surface electrode 40 is deposited on the interlayer insulating film 20. The front-surface electrode 40 in the transistor part 101 is electrically connected to the emitter regions 4a and 4b and the contact regions 5a and 5b via the respective contact plugs 30 so as to serve as an emitter electrode. The front-surface electrode 40 in the diode part 102 is electrically connected to the anode region 13 via the respective contact plugs 30 so as to serve as an anode electrode. The front-surface electrode 40 as used herein can be made from metal such as aluminum (Al), an Al alloy, or copper (Cu). Examples of Al alloys include an Al-silicon alloy, an Al—Si—Cu alloy, and an Al—Cu alloy.

FIG. 1 omits the illustration of the interlayer insulating film 20, the front-surface electrode 40, the side-wall implantation regions 16a and 16b, and the suppression regions 17a and 17b illustrated in FIG. 2. The contact plug 30 has a straight (stripe-like) part extending parallel to the longitudinal direction of the respective gate trenches 11 in the planar pattern. The contact region 15 hidden under the contact plug 30 also extends parallel to the contact plug 30. The respective contact plugs 30 in the transistor part 101 are arranged between the emitter regions 4a and 4b and the contact regions 5a and 5b. The respective contact plugs 30 in the diode part 102 are arranged between the anode regions 13. The respective contact plugs 30 do not necessarily have a straight shape, and may have any other shape such as a hole-like shape.

As illustrated in FIG. 2, a field-stop (FS) layer 8 of n-type having a higher impurity concentration than the drift layer 1 is deposited on the bottom surface side of the drift layer 1 in the transistor part 101 and the diode part 102. The top surface of the FS layer 8 is in contact with the bottom surface of the drift layer 1. The FS layer 8 prevents a depletion layer that expands from the bottom surface side of the base region 3 and the anode region 13 from reaching a second main electrode region (a collector region) 9 and a cathode region 12 described below.

The collector region 9 of p⁺-type is deposited on the bottom surface side of the FS layer 8 in the transistor part 101. The top surface of the collector region 9 is in contact with the bottom surface of the FS layer 8. The collector region 9 has a higher impurity concentration than the base region 3. The cathode region 12 of n⁺-type having a higher impurity concentration than the FS layer 8 is deposited on the bottom surface side of the FS layer 8 in the diode part 102. The top surface of the cathode region 12 is in contact with the bottom surface of the FS layer 8. The cathode region 12 is provided at the same depth as the collector region 9. The side surface of the cathode region 12 is in contact with the side surface of the collector region 9.

A rear-surface electrode 50 is deposited on the bottom surface side of the collector region 9 and the cathode region 12. The rear-surface electrode 50 is made of a single film of gold (Au) or a metallic film including titanium (Ti), nickel (Ni), and gold (Au) stacked together in this order, for example. The rear-surface electrode 50 serves as a collector electrode in the transistor part 101, and serves as a cathode electrode in the diode part 102.

The semiconductor device according to the first embodiment during the operation leads the front-surface electrode 40 to serve as a ground potential and applies a positive voltage to the rear-surface electrode 50, and causes an inversion layer (a channel) to be formed in the base region 3 on the side surface side of the respective gate trenches 11 so as to be led to be in an ON-state when a positive voltage of a threshold or greater is applied to the gate electrode 7. In the ON-state, a current flows from the rear-surface electrode 50 toward the front-surface electrode 40 through the collector region 9, the FS layer 8, the drift layer 1, the accumulation layer 2, the inversion layer of the base region 3, and the emitter regions 4a and 4b.

When the voltage applied to the gate electrode 7 is smaller than the threshold, the semiconductor device is led to be in an OFF-state since no inversion channel is formed in the base region 3, and no current flows from the rear-surface electrode 50 toward the front-surface electrode 40. The diode part 102 allows a freewheeling current to flow in the opposite direction when the transistor part 101 is turned off

<Method of Manufacturing Semiconductor Device>

An example of a method of manufacturing the semiconductor device according to the first embodiment is described below. The method of manufacturing the semiconductor device described below is one of examples, and it should be understood that the semiconductor device according to the first embodiment can be achieved by various manufacturing methods including modified examples within the scope of the appended claims.

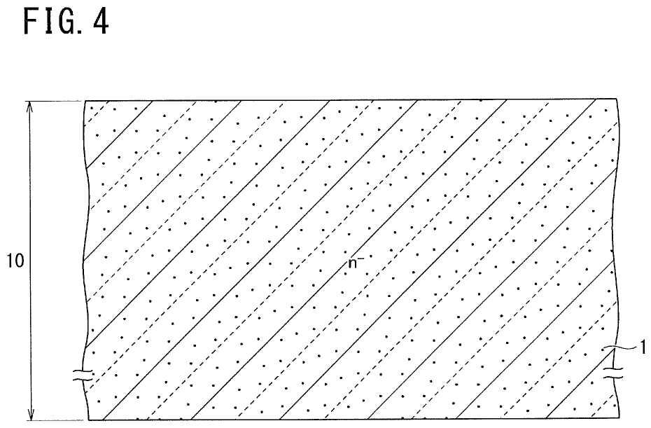

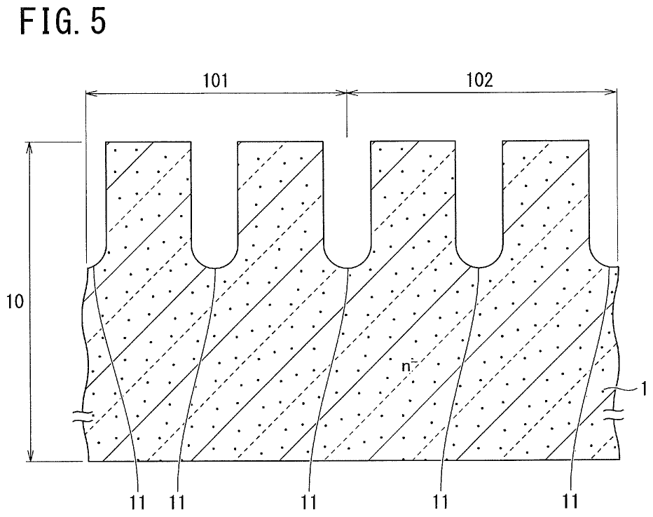

First, the semiconductor substrate 10 made of a silicon (Si) wafer of the first conductivity-type (n⁻-type) is prepared, as illustrated in FIG. 4. Next, the drift layer 1 is partly and selectively removed from the top surface side of the semiconductor substrate 10 by photolithography and dry etching. The plural gate trenches 11 are thus formed at the upper part of the semiconductor substrate 10, as illustrated in FIG. 5.

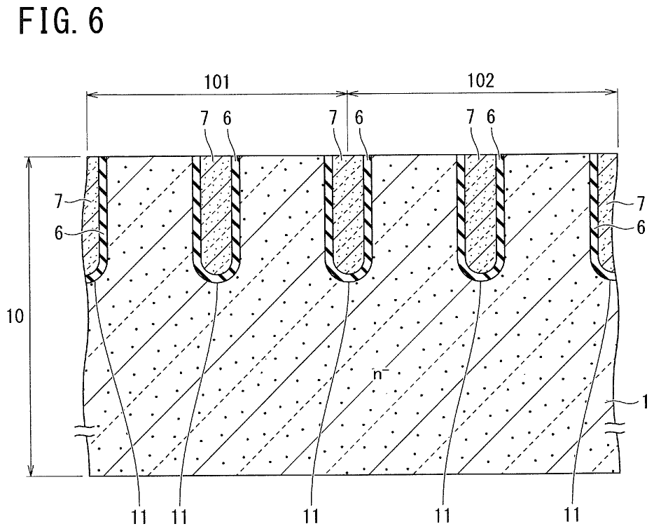

Next, the gate insulating film 6 is formed on the bottom surface and the side surface of the respective gate trenches 11 by a thermal oxidation method or a chemical vapor deposition (CVD) method, for example. A polysilicon film (a doped polysilicon film) heavily doped with impurity ions such as phosphorus (P) or boron (B) is deposited so as to fill the inside of the respective gate trenches 11 via the gate insulating film 6 by the CVD method and the like. The polysilicon film and the gate insulating film 6 on the semiconductor substrate 10 are then selectively removed by photolithography and dry etching. The insulated gate electrode structure (6, 7) implemented by the gate insulating film 6 and the gate electrode 7 of the polysilicon film is thus formed in the respective gate trenches 11, as illustrated in FIG. 6.

Next, p-type impurity ions such as boron (B) are implanted into the entire top surface of the drift layer 1 so as to form the p⁻-type base region 3 in the transistor part 101 simultaneously together with the p⁻-type anode region 13 in the diode part 102. The photoresist film is then removed.

Next, a photoresist film is applied on the top surface of the drift layer 1, and is then delineated by photolithography. Using the delineated photoresist film as a mask for ion implantation, n-type impurity ions such as phosphorus (P) or arsenic (As) are implanted so as to form the n-type accumulation layer 2 in the transistor part 101. The photoresist film is then removed.

Next, a photoresist film is applied on the top surface of the drift layer 1, and is then delineated by photolithography. Using the delineated photoresist film as a mask for ion implantation, p-type impurity ions such as boron (B) are implanted so as to form the p⁺-type contact regions 5a and 5b in the transistor part 101 (refer to FIG. 1). The photoresist film is then removed.

Next, a photoresist film is applied on the top surface of the drift layer 1, and is then delineated by photolithography. Using the delineated photoresist film as a mask for ion implantation, n-type impurity ions are implanted so as to form the n⁺-type emitter regions 4a and 4b in the transistor part 101. The photoresist film is then removed. The order of the ion implantation for forming the accumulation layer 2, the ion implantation for forming the base region 3 and the anode region 13, the ion implantation for forming the emitter regions 4a and 4b, and the ion implantation for forming the contact regions 5a and 5b can be determined and changed as appropriate.

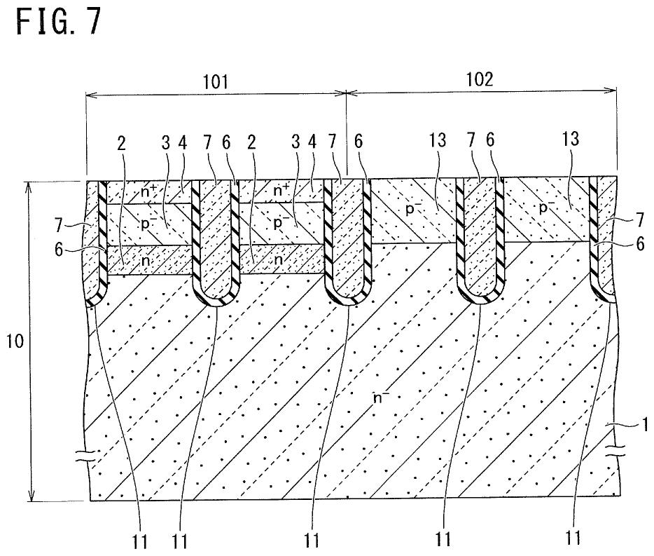

Next, the impurity ions implanted into the semiconductor substrate 10 are activated by annealing. The upper part of the semiconductor substrate 10 in the transistor part 101 is thus provided with the n-type accumulation layer 2, the p⁻-type base region 3, the n⁺-type emitter region 4, and the p⁺-type contact region (refer to FIG. 1), as illustrated in FIG. 7. Similarly, the upper part of the semiconductor substrate 10 in the diode part 102 is provided with the p⁺-type anode region 13.

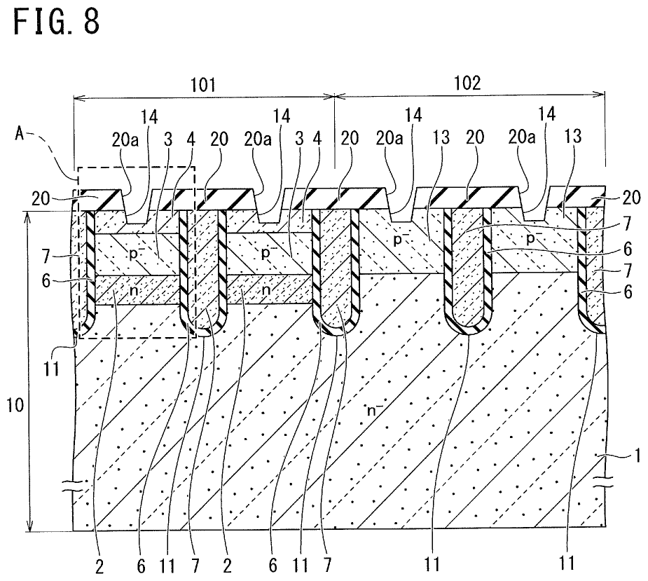

Next, the interlayer insulating film 20 is formed by the CVD method and the like on the respective top surfaces of the insulated gate electrode structures (6, 7), the emitter region 4, and the anode region 13. A photoresist film is then applied on the top surface of the interlayer insulating film 20, and is delineated by photolithography. Using the delineated photoresist film as a mask for etching, the interlayer insulating film 20 is partly and selectively removed by dry etching. This step opens the contact holes 20a to which the emitter region 4 and the anode region 13 are partly exposed. In addition, using the interlayer insulating film 20 as a mask for etching, the emitter region 4 and the anode region 13 are partly and selectively removed by dry etching. The contact trenches 14 are thus formed integrally with the contact holes 20a at the upper parts of the emitter region 4 and the anode region 13, as illustrated in FIG. 8.

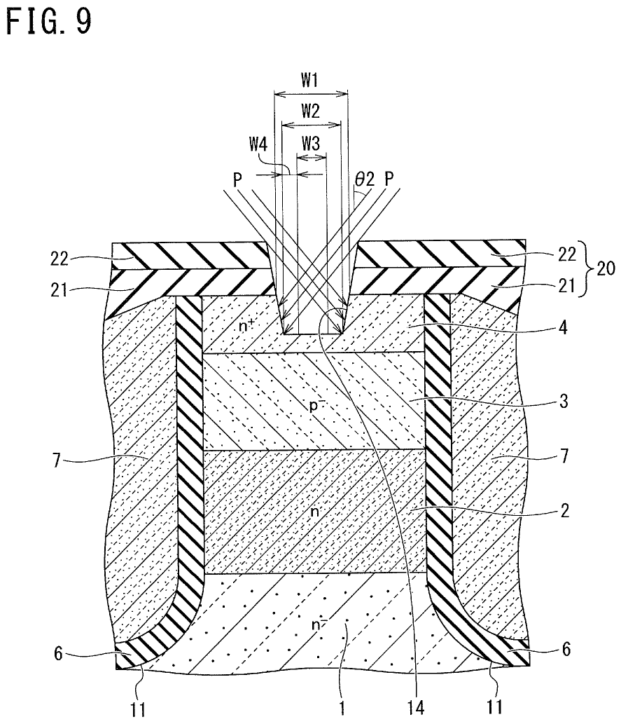

FIG. 9 is a cross-sectional process view continued from FIG. 8, and is an enlarged view illustrating region A in FIG. 8. As illustrated in FIG. 9, the n-type impurity ions such as phosphorus (P) are implanted into the side wall surfaces on both sides of the contact trench 14 in both of the diagonally upper-side directions that are diagonal with respect to the vertical direction perpendicular to the bottom surface of the contact trench 14. Examples of impurity ions to be implanted include phosphorus (P), arsenic (As), and nitrogen (N), and P is used in this embodiment, for example. The ion implantation into one of the side wall surfaces of the contact trench 14 (on the right side in FIG. 9) and the ion implantation into the other side wall surface of the contact trench 14 (on the left side in FIG. 9) may be executed either in both directions simultaneously or in each direction sequentially.

An implantation angle θ2 of the ion implantation is in a range of about 5 degrees or greater and 15 degrees or smaller, for example, with respect to the direction perpendicular to the bottom surface of the contact trench 14. The implantation angle θ2 of the ion implantation can be regulated as appropriate depending on the depth, the opening width, the tapered angle, and the like of the contact trench 14. An acceleration energy upon the ion implantation is in a range of about 30 keV or greater and 200 keV or less, for example. A dose of the impurity ions to be implanted is in a range of about 3×10¹³ ions/cm 2 or greater and 1×10¹⁵ ions/cm² or smaller, for example, and is preferably in a range of about 5×10¹³ ions/cm² or greater and 1×10¹⁴ ions/cm² or smaller. The ion implantation of the n-type impurity ions executed under the conditions as described above can avoid a lateral diffusion of the p-type impurity ions implanted in the subsequent step. When the contact plugs 30 each have other shapes other than that as described above, such as a hole-like shape, the impurity ions can be implanted in several directions sequentially in different steps.

The n-type impurity ions illustrated in FIG. 9 are implanted into the entire side wall surfaces of the contact trench 14. The ion implantation is executed with respect to the regions encompassing the corners defined by the bottom surface and the side wall surfaces of the contact trench 14. A width W4 of the end part of the contact trench 14 into which the impurity ions are implanted is in a range of about 1/10 or greater and ¼ or smaller of the width W2 of the entire bottom surface of the contact trench 14, for example. The impurity ions may be implanted only into the entire side wall surfaces of the contact trench 14 without including the corners defined by the bottom surface and the side wall surfaces of the contact trench 14 instead.

The ion implantation is executed with respect to the parts excluding the middle of the bottom surface of the contact trench 14. A width W3 of the middle part not implanted with the impurity ions is in a range of about ½ or greater and ⅘ or smaller of the width W2 of the entire bottom surface of the contact trench 14, for example. The exclusion of the middle part of the bottom surface of the contact trench 14 upon the ion implantation can avoid an increase in contact resistance. The ion implantation executed under the conditions as described above can prevent the p-type impurity ions implanted into the middle part of the bottom surface of the contact trench 14 from being diffused in the lateral direction while avoiding an influence on the resistance value of the contact region 15. The ion implantation of the n-type impurity ions does not necessarily avoid the middle part of the bottom surface of the contact trench 14 when the dose of the n-type impurity ions implanted into the side wall surfaces of the contact trench 14 is smaller by one digit or more than the dose of the p-type impurity ions implanted into the bottom surface of the contact trench 14, since the amount of the n-type impurity ions implanted into the side wall surfaces of the contact trench 14 is decreased to a level that can be ignored.

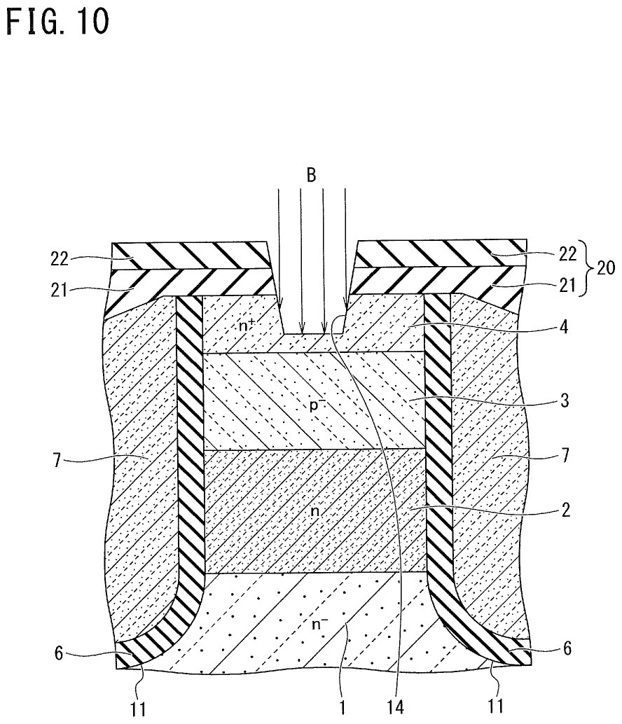

Next, as illustrated in FIG. 10, the p-type impurity ions are implanted into the bottom surface of the contact trench 14. The ion implantation of the p-type impurity ions is executed in the direction substantially perpendicular to the bottom surface of the contact trench 14, for example. The p-type impurity ions to be implanted can be boron (B), boron fluoride (BF₂), or aluminum (Al), for example, and BF₂ is used in this embodiment. The p-type impurity ions illustrated in FIG. 10 are implanted not only into the bottom surface of the contact trench 14 but also into the side wall surfaces on both sides of the contact trench 14 when having a tapered shape.

The dose of the p-type impurity ions implanted as illustrated in FIG. 10 is in a range of about 3×10¹⁵ ions/cm² or greater and 5×10¹⁵ ions/cm² or smaller, for example. With regard to the comparison between the n-type impurity ions implanted as illustrated in FIG. 9 and the p-type impurity ions implanted as illustrated in FIG. 10, the dose of the n-type impurity ions illustrated in FIG. 9 is smaller than the dose of the p-type impurity ions implanted in the vertical direction illustrated in FIG. 10. The dose of the n-type impurity ions illustrated in FIG. 9 is in a range of about 1% or greater and 10% or smaller, for example, with respect to the dose of the p-type impurity ions implanted in the vertical direction illustrated in FIG. 10.

The acceleration energy upon the ion implantation of the p-type impurity ions illustrated in FIG. 10 is in a range of about 10 keV or greater and 50 keV or less, for example. With regard to the comparison between the n-type impurity ions implanted as illustrated in FIG. 9 and the p-type impurity ions implanted as illustrated in FIG. 10, the acceleration energy upon the ion implantation of the n-type impurity ions illustrated in FIG. 9 is higher than the acceleration energy upon the ion implantation of the p-type impurity ion illustrated in FIG. 10. The n-type impurity ions illustrated in FIG. 9 are thus implanted deeper than the p-type impurity ions illustrated in FIG. 10 through the side wall surfaces of the contact trench 14 in the direction perpendicular to the side wall surface.

The p-type impurity ions implanted into the bottom surface of the contact trench 14 illustrated in FIG. 10 are distributed according to a Gaussian distribution depending on ion species and the acceleration energy in the depth direction. The p-type impurity ions collide against interstitial atoms in the semiconductor substrate 10 to be diffused and are distributed also in the lateral direction, and thus spread over into a width wider than the width W2 of the bottom surface of the contact trench 14. The p-type impurity ions implanted into the respective side wall surfaces of the contact trench 14 also collide against the interstitial atoms in the semiconductor substrate 10 to be diffused and are distributed also in the lateral direction.

While the method of manufacturing the semiconductor device according to the first embodiment is illustrated with the case of executing the ion implantation of the p-type impurity ions illustrated in FIG. 10 after the ion implantation of the n-type impurity ions illustrated in FIG. 9, the order of the ion implantations is determined as appropriate. The ion implantation of the n-type impurity ions illustrated in FIG. 9 may be executed after the ion implantation of the p-type impurity ions illustrated in FIG. 10 instead.

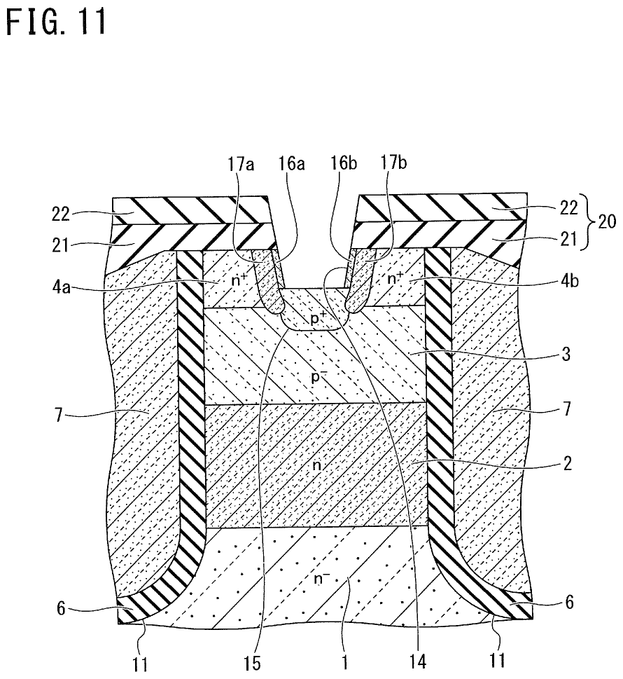

The n-type impurity ions illustrated in FIG. 9 and the p-type impurity ions illustrated in FIG. 10 are activated by annealing such as rapid thermal annealing (RTA) after the ion implantations of the n-type impurity ions and the p-type impurity ions. The n-type impurity ions and the p-type impurity ions are scarcely diffused in the case of the execution of the RTA. This annealing leads the p⁺-type contact region 15 to be formed under the bottom surface of the contact trench 14 so as to be in contact with the base region 3, as illustrated in FIG. 11. The contact region 15 is the region formed such that the p-type impurity ions illustrated in FIG. 10 are implanted into the bottom surface of the contact trench 14. The emitter region 4 is divided by the contact region 15 into the emitter regions 4a and 4b in contact with the contact region 15.

The n⁺-type side-wall implantation regions 16a and 16b are formed in the parts of the emitter regions 4a and 4b in contact with the side wall surfaces of the contact trench 14. The side-wall implantation regions 16a and 16b are the regions formed such that the p-type impurity ions illustrated in FIG. 10 are implanted into the side wall surfaces of the contact trench 14.

The n⁺-type suppression regions 17a and 17b are formed in the parts of the emitter regions 4a and 4b on the side in contact with the side surfaces of the side-wall implantation regions 16a and 16b opposite to the side wall surfaces of the contact trench 14. The suppression regions 17a and 17b are the regions formed such that the n-type impurity ions illustrated in FIG. 9 are implanted into the side wall surfaces of the contact trench 14 and the corners defined by the side wall surfaces and the bottom surface of the contact trench 14.

The presence of the suppression regions 17a and 17b compensates (cancels out) the p-type impurity ions implanted into the side-wall implantation regions 16a and 16b, so as to decrease a diffusion of the p-type impurity ions in the side-wall implantation regions 16a and 16b in the lateral direction. Further, the lower parts of the suppression regions 17a and 17b compensate (cancel out) the p-type impurity ions around the upper side surfaces of the contact region 15, so as to decrease a diffusion of the p-type impurity ions in the contact region 15 in the lateral direction.

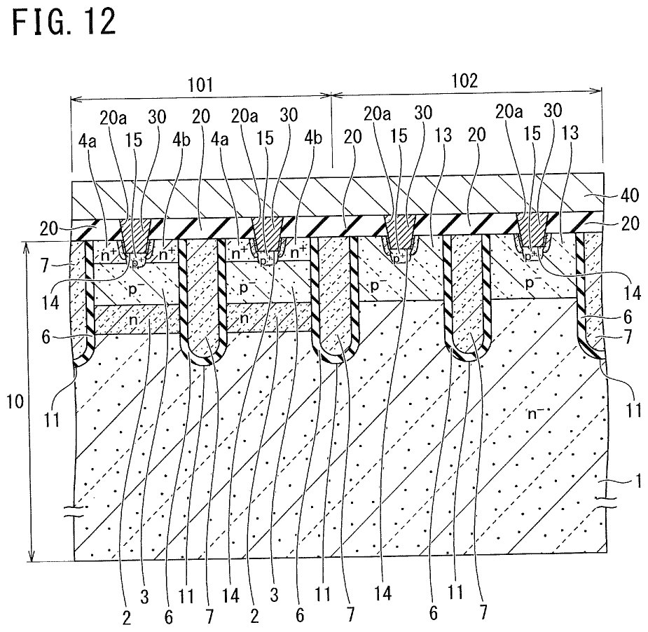

Next, the contact trenches 14 and the contact holes 20a are filled with the contact plugs 30 via barrier metal films by sputtering or vapor deposition, and dry etching, for example. Next, the front-surface electrode 40 is deposited on the top surfaces of the contact plugs 30 and the interlayer insulating film 20 by sputtering or vapor deposition, for example, as illustrated in FIG. 12.

Next, the semiconductor substrate 10 is ground from the bottom surface side by backgrinding or chemical mechanical polishing (CMP), for example, so that the thickness of the semiconductor substrate 10 is adjusted to have an appropriate thickness of a final product. Next, n-type impurity ions such as phosphorus (P) or selenium (Se) for forming the n-type FS layer 8 are implanted into the entire bottom surface of the semiconductor substrate 10.

Next, p-type impurity ions such as boron (B) for forming the p⁺-type collector region 9 are implanted into the entire bottom surface of the semiconductor substrate 10 with lower acceleration energy than that upon the ion implantation executed for forming the n-type FS layer 8.

Next, a photoresist film is applied to the bottom surface of the drift layer 1, and is delineated by photolithography. Using the delineated photoresist film as a mask for ion implantation, n-type impurity ions such as phosphorus (P) are implanted so as to form the n⁺-type cathode region 12.

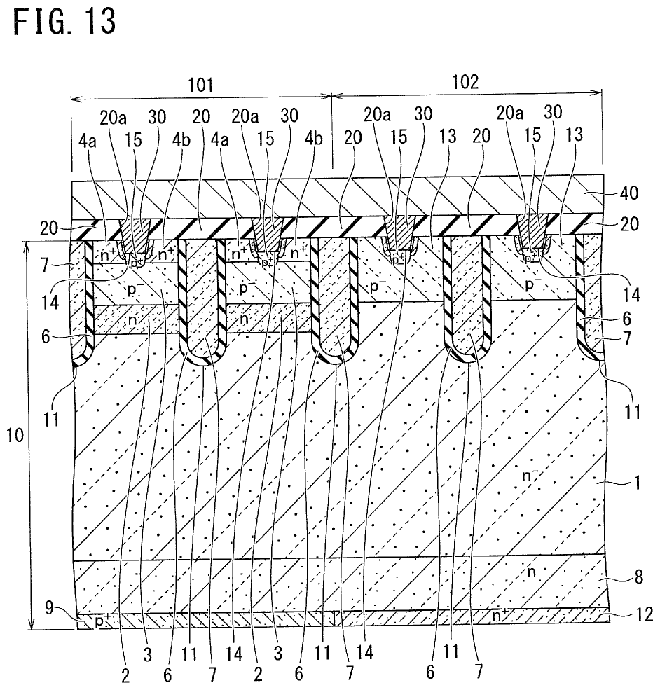

Next, the impurity ions implanted into the semiconductor substrate 10 are activated by annealing. This step forms the FS layer 8 under the semiconductor substrate 10, as illustrated in FIG. 13. The p⁺-type collector region 9 is also formed in the transistor part 101, and the n⁺-type cathode region 12 is also formed in the diode part 102.

Next, the rear-surface electrode 50 including gold (Au) is formed on the entire bottom surface of the semiconductor substrate 10 by sputtering or vapor deposition, for example. Thereafter, the semiconductor substrate 10 is cut (diced) into individual pieces, so as to complete the semiconductor device according to the first embodiment as illustrated in FIG. 1 to FIG. 3.

A method of manufacturing a semiconductor device of a comparative example is described below. The method of manufacturing the semiconductor device of the comparative example differs from the method of manufacturing the semiconductor device according to the first embodiment, which executes both the ion implantation of the n-type impurity ions illustrated in FIG. 9 and the ion implantation of the p-type impurity ions illustrated in FIG. 10, in only executing the ion implantation of the p-type impurity ions illustrated in FIG. 10 without executing the ion implantation of the n-type impurity ions illustrated in FIG. 9. The other steps of the method of manufacturing the semiconductor device of the comparative example are the same as those of the method of manufacturing the semiconductor device according to the first embodiment.

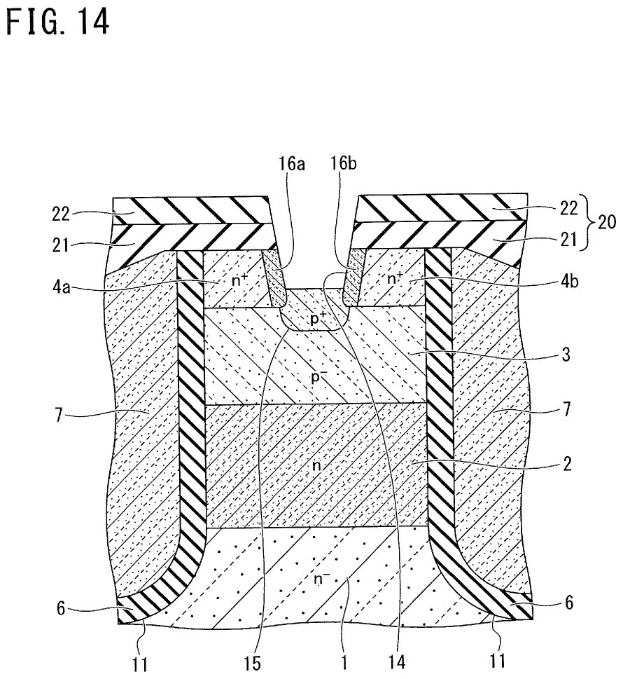

The execution of the annealing after the ion implantation of the p-type impurity ions illustrated in FIG. 10 leads the p⁺-type contact region 15 to be formed under the bottom surface of the contact trench 14, as illustrated in FIG. 14. The n-type side-wall implantation regions 16a and 16b are formed in the parts of the emitter regions 4a and 4b in contact with the side wall surfaces of the contact trench 14, while the suppression regions 17a and 17b as illustrated in FIG. 11 are not formed in this case.

In the method of manufacturing the semiconductor device of the comparative example, the p-type impurity ions implanted into the bottom surface and the side wall surfaces of the contact trench 14 collide against the interstitial atoms in the semiconductor substrate 10 to be diffused and are distributed also in the lateral direction upon the ion implantation of the p-type impurity ions illustrated in FIG. 10, as in the case of the method of manufacturing the semiconductor device according to the first embodiment. When the width of the mesa part between the respective gate trenches 11 is decreased in association with the minimization, the p-type impurity ions distributed upon the ion implantation of the p-type impurity ions illustrated in FIG. 10 reach the regions adjacent to the gate trenches 11, which increases the impurity concentration (the channel carrier concentration) in the base region 3. This causes a fluctuation (an increase) or a variation in gate threshold voltage. To stabilize the electrical properties, the minimization of the opening width W1 of the contact trench 14 or the width of the mesa part between the respective gate trenches 11 is inevitably limited.

In contrast, the method of manufacturing the semiconductor device according to the first embodiment executes the ion implantation of the n-type impurity ions illustrated in FIG. 9 to dope the n-type impurity ions that are the reverse conducing type of the p-type impurity ions implanted as illustrated in FIG. 10 to form the suppression regions 17a and 17b so as to cover the side surfaces of the side-wall implantation regions 16a and 16b. This can compensate the p-type impurity ions implanted into the side wall surfaces of the contact trench 14 illustrated in FIG. 10, so as to avoid a diffusion of the p-type impurity ions in the lateral direction.

In addition, the provision of the suppression regions 17a and 17b for covering the upper parts of the side surfaces of the contact region 15 can avoid a diffusion of the p-type impurity ions in the contact region 15 in the lateral direction. Further, the respective lower parts of the suppression regions 17a and 17b extend toward the bottom surface of the contact trench 14 to cover the circumference of the corners defined by the bottom surface and the side wall surfaces of the contact trench 14, so as to further suppress the diffusion of the p-type impurity ions in the contact region 15 in the lateral direction.

As described above, the suppression of the diffusion in the lateral direction of the p-type impurity ions implanted into the side wall surfaces of the contact trench 14 and the p-type impurity ions in the contact region 15 under the bottom surface of the contact trench 14 can suppress a fluctuation (an increase) or a variation in the gate threshold voltage. This can decrease the opening width W1 of the contact trench 14 and the width of the mesa part between the respective gate trenches 11, so as to achieve the minimization of the semiconductor device accordingly.

Further, the manufacturing method according to the first embodiment does not need to use an ultra-shallow implantation device such as a plasma immersion doping device or a cluster ion implantation device other than the ion implantation device, and thus can enable the shallow junction formation by use of a conventional ion implantation device.

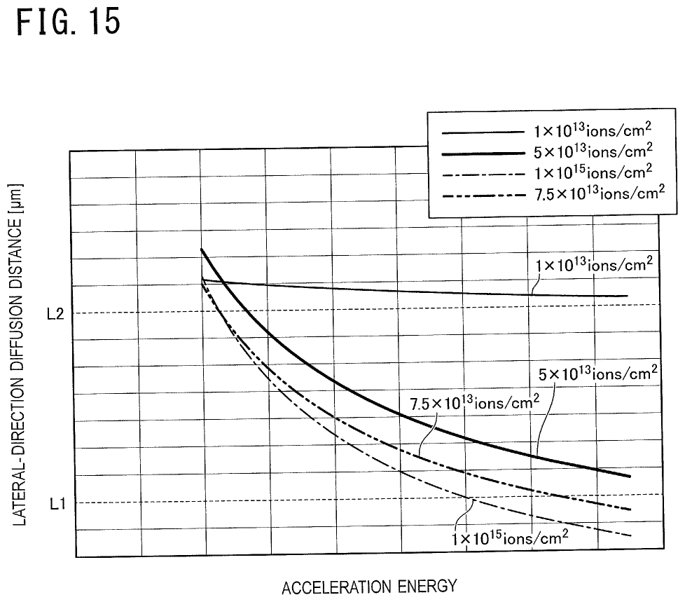

FIG. 15 is a graph showing results of a simulation for examining a relation between the dose of the n-type impurity ions, the acceleration energy, and the lateral-direction diffused distance of P upon the ion implantation illustrated in FIG. 9. The ion implantation of the n-type impurity ions illustrated in FIG. 9 was executed under the conditions in which P was used as the n-type impurity ions, the acceleration energy was changed in a range of 40 keV to 140 keV, and the dose was changed in a range of 1×10¹³ ions/cm² to 1×10¹⁵ ions/cm². The ion implantation of the p-type impurity ions illustrated in FIG. 10 was executed under the conditions in which BF₂ was used as the p-type impurity ions, the acceleration energy was set to 30 keV, the dose was set to 3×10¹⁵ ions/cm², and the implantation angle θ2 was set to zero degrees.

The simulation revealed that, as shown in FIG. 15, the diffusion of P in the lateral direction was reduced as the dose and the acceleration energy were increased. The simulation also revealed that the diffusion in the lateral direction in the case of the dose in the range of 5×10¹³ ions/cm² to 1×10¹⁵ ions/cm² could be reduced to about a lateral-direction diffusion distance L1 that is half of a lateral-direction diffusion distance L2 in the case of the dose of 1×10¹³ ions/cm².

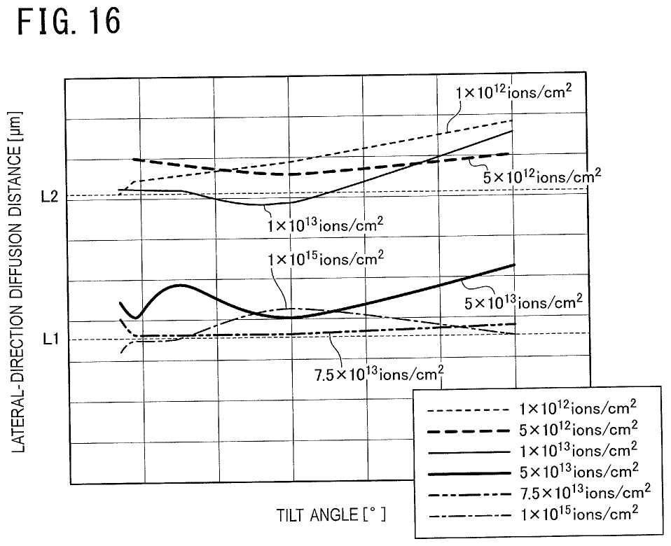

FIG. 16 is a graph showing results of a simulation for examining a relation between the dose of the n-type impurity ions, the ion implantation angle (a tilt angle), and the lateral-direction diffused distance of P upon the ion implantation illustrated in FIG. 9. The ion implantation of the n-type impurity ions illustrated in FIG. 9 was executed under the conditions in which P was used as the n-type impurity ions, the acceleration energy was set to 120 keV, the dose was changed in a range of 1×10¹² ions/cm² to 1×10¹⁵ ions/cm², and the implantation angle θ2 was changed in a range of 9 degrees to 13 degrees. The ion implantation of the p-type impurity ions illustrated in FIG. 10 was executed under the conditions in which BF₂ was used as the p-type impurity ions, the acceleration energy was set to 30 keV, the dose was set to 3×10¹⁵ ions/cm², and the implantation angle θ2 was set to zero degrees.

The simulation revealed that, as shown in FIG. 16, the diffusion of P in the lateral direction was reduced as the dose was increased. The simulation also revealed that the diffusion in the lateral direction in the case of the dose in the range of 5×10¹³ ions/cm² to 1×10¹⁵ ions/cm² could be reduced to about the latera-direction diffusion distance L1 that is half of the lateral-direction diffusion distance L2 in the case of the dose of 1×10¹² ions/cm² to 1×10¹³ ions/cm².

### Second Embodiment

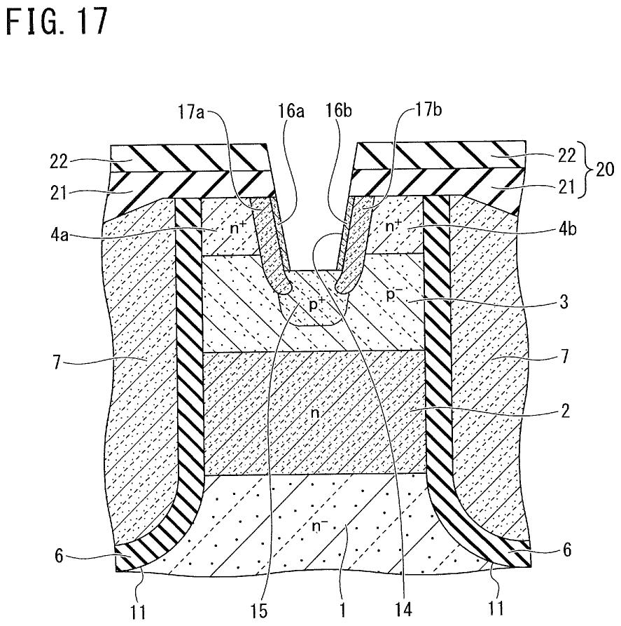

A method of manufacturing a semiconductor device according to a second embodiment differs from the method of manufacturing the semiconductor device according to the first embodiment in providing the contact trench 14 so as to penetrate the n⁺-type emitter regions 4a and 4b, as illustrated in FIG. 17. The bottom surface of the contact trench 14 is located inside the p⁻-type base region 3.

The method of manufacturing the semiconductor device according to the second embodiment implants the n-type impurity ions into the side wall surfaces on both sides of the contact trench 14 in the directions that are diagonal with respect to the vertical direction perpendicular to the bottom surface of the contact trench 14 illustrated in FIG. 17, as in the case of the ion implantation of the n-type impurity ions illustrated in FIG. 9. The impurity ions in this case are implanted into the regions encompassing the corners defined by the bottom surface and the side wall surfaces of the contact trench 14 while avoiding the middle part of the bottom surface of the contact trench 14. The p-type impurity ions are also implanted into the bottom surface of the contact trench 14 in the direction perpendicular to the bottom surface of the contact trench 14 illustrated in FIG. 17, as in the case of the ion implantation of the p-type impurity ions illustrated in FIG. 10.

The annealing is then executed so as to form the p⁺-type contact region 15 under the bottom surface of the contact trench 14, as illustrated in FIG. 17. The contact region 15 is formed inside the base region 3. The n⁺-type side-wall implantation regions 16a and 16b are formed such that the side surfaces are in contact with the side wall surfaces of the contact trench 14. The n⁺-type suppression regions 17a and 17b are also formed so as to be in contact with the side surfaces of the side-wall implantation regions 16a and 16b opposite to the side in contact with the side wall surfaces of the contact trench 14.

The other steps of the method of manufacturing the semiconductor device according to the second embodiment are the same as those of the method of manufacturing the semiconductor device according to the first embodiment, and overlapping explanations are not repeated below.

The method of manufacturing the semiconductor device according to the second embodiment, in which the contact trench 14 penetrates the emitter regions 4a and 4b, can also avoid the lateral diffusion of the p-type impurity ions implanted into the side wall surfaces of the contact trench 14 and the p-type impurity ions in the contact region 15 under the bottom surface of the contact trench 14, so as to suppress a fluctuation (an increase) or a variation in the gate threshold voltage accordingly.

### Third Embodiment

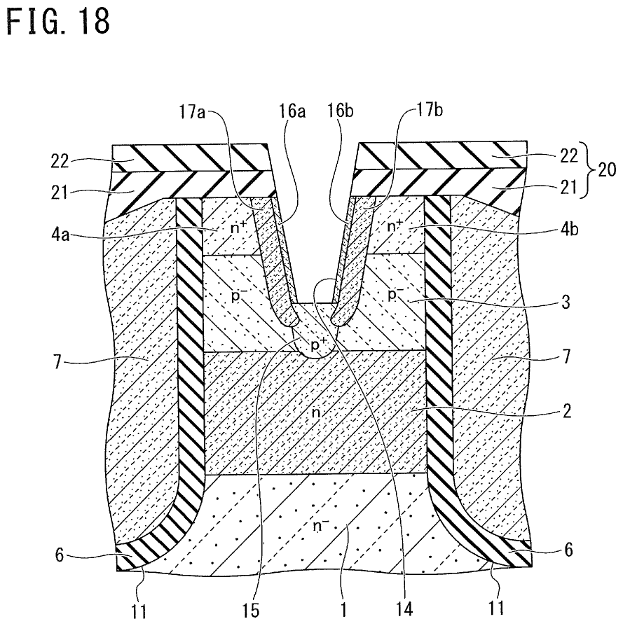

A method of manufacturing a semiconductor device according to a third embodiment has a process common to the method of manufacturing the semiconductor device according to the second embodiment in forming the contact trench 14 so as to penetrate the n⁺-type emitter regions 4a and 4b, as illustrated in FIG. 18. The method of manufacturing the semiconductor device according to the third embodiment differs from the method of manufacturing the semiconductor device according to the second embodiment in that the p⁺-type contact region 15 under the bottom surface of the contact trench 14 penetrates the p⁻-type base region 3 so as to reach the upper part of the n-type accumulation layer 2.

The method of manufacturing the semiconductor device according to the third embodiment implants the n-type impurity ions into the respective side wall surfaces of the contact trench 14 in the directions that are diagonal with respect to the vertical direction perpendicular to the bottom surface of the contact trench 14 illustrated in FIG. 18, as in the case of the ion implantation of the n-type impurity ions illustrated in FIG. 9. The impurity ions in this case are implanted into the regions encompassing the corners defined by the bottom surface and the side wall surfaces of the contact trench 14 while avoiding the middle part of the bottom surface of the contact trench 14. The p-type impurity ions are also implanted into the bottom surface of the contact trench 14 in the direction perpendicular to the bottom surface of the contact trench 14 illustrated in FIG. 18, as in the case of the ion implantation of the p-type impurity ions illustrated in FIG. 10.

The annealing is then executed so as to form the p⁺-type contact region 15 under the bottom surface of the contact trench 14, as illustrated in FIG. 18. The n⁺-type side-wall implantation regions 16a and 16b are formed such that the side surfaces are in contact with the side wall surfaces of the contact trench 14. The n⁺-type suppression regions 17a and 17b are also formed so as to be in contact with the side surfaces of the side-wall implantation regions 16a and 16b opposite to the side in contact with the side wall surfaces of the contact trench 14.

The other steps of the method of manufacturing the semiconductor device according to the third embodiment are the same as those of the method of manufacturing the semiconductor device according to the first embodiment, and overlapping explanations are not repeated below.

The method of manufacturing the semiconductor device according to the third embodiment, in which the contact trench 14 penetrates the emitter regions 4a and 4b, and the contact region 15 reaches the upper part of the accumulation layer 2, can also avoid the lateral diffusion of the p-type impurity ions implanted into the side wall surfaces of the contact trench 14 and the p-type impurity ions in the contact region 15 under the bottom surface of the contact trench 14, so as to suppress a fluctuation (an increase) or a variation in the gate threshold voltage accordingly.

### Fourth Embodiment

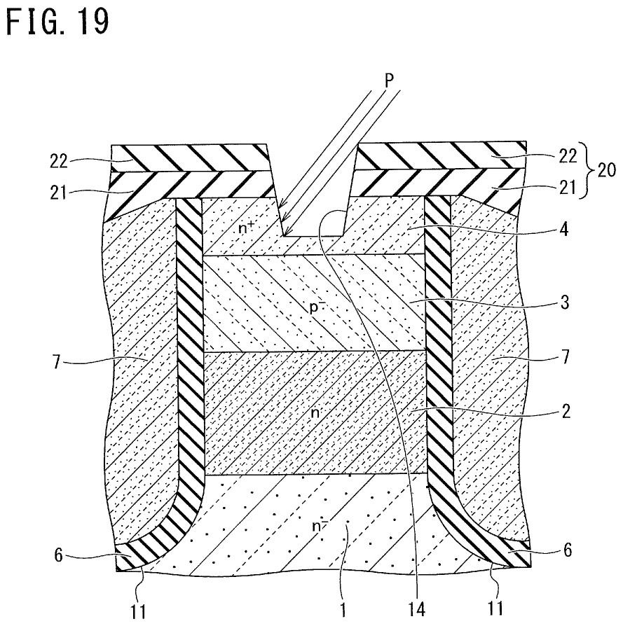

A method of manufacturing a semiconductor device according to a fourth embodiment differs from the method of manufacturing the semiconductor device according to the first embodiment in that one of the gate trenches 11 next to each other (on the right side in FIG. 19) is a dummy trench part, and the other gate trench 11 (on the left side in FIG. 19) is a gate trench part serving as an IGBT, as illustrated in FIG. 19.

The method of manufacturing the semiconductor device according to the fourth embodiment implants the n-type impurity ions into the one of the side wall surfaces of the contact trench 14 toward the gate trench 11 on the left side that is the gate trench part serving as the IGBT, as illustrated in FIG. 19, instead of the ion implantation of the n-type impurity ions illustrated in FIG. 9. The impurity ions in this case are implanted into the region encompassing the corner defined by the bottom surface and the side wall surface of the contact trench 14 while avoiding the middle part of the bottom surface of the contact trench 14. The n-type impurity ions are not implanted into the side wall surface of the contact trench 14 toward the gate trench 11 on the right side that is the dummy trench part.

The p-type impurity ions are implanted into the bottom surface of the contact trench 14 in the direction perpendicular to the bottom surface of the contact trench 14 illustrated in FIG. 19, as in the case of the ion implantation of the p-type impurity ions illustrated in FIG. 10.

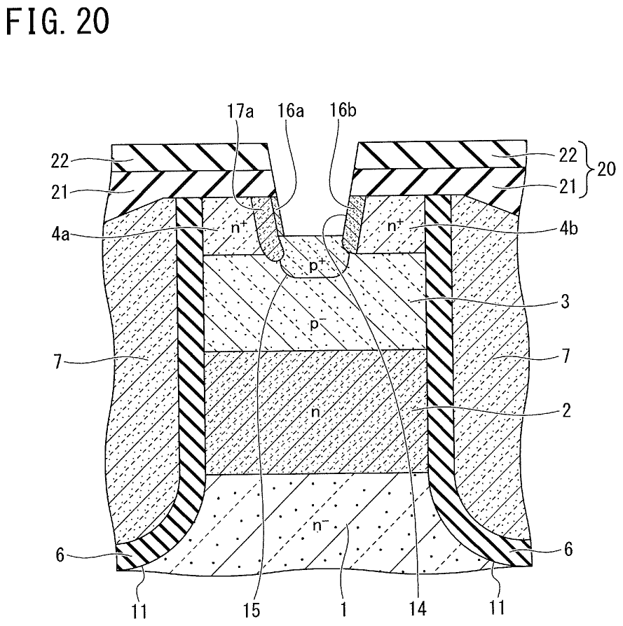

The annealing is then executed so as to form the p⁺-type contact region 15 under the bottom surface of the contact trench 14, as illustrated in FIG. 20. The n⁺-type side-wall implantation regions 16a and 16b are formed such that the side surfaces are in contact with the side wall surfaces of the contact trench 14. The n⁺-type suppression region 17a is formed toward the gate trench 11 on the left side that is the gate trench part so as to be in contact with the side surface of the side-wall implantation region 16a opposite to the side in contact with the side wall surface of the contact trench 14. The n⁺-type suppression region is not formed toward the gate trench 11 on the right side that is the dummy trench part.

The other steps of the method of manufacturing the semiconductor device according to the fourth embodiment are the same as those of the method of manufacturing the semiconductor device according to the first embodiment, and overlapping explanations are not repeated below.

The method of manufacturing the semiconductor device according to the fourth embodiment implants the n-type impurity ions selectively into one of the side wall surfaces of the contact trench 14 serving as an element when one of the gate trenches 11 next to each other is the dummy trench part not serving as an element. This can avoid the lateral diffusion of the p-type impurity ions implanted into the side wall surface of the contact trench 14 and the p-type impurity ions in the contact region 15 under the bottom surface of the contact trench 14 toward the side serving as an element, so as to suppress a fluctuation (an increase) or a variation in the gate threshold voltage accordingly.

### Other Embodiments

As described above, the first to fourth embodiments have been described, but it should not be understood that the description and drawings implementing a portion of this disclosure limit the invention. Various alternative embodiments, examples, and operational techniques will be apparent to those skilled in the art from this disclosure.

While the semiconductor devices according to the first to fourth embodiments have been illustrated with the RC-IGBT, the present invention can also be applied to any other IGBTs other than the RC-IGBT. For example, the present invention may be applied to a reverse-blocking insulated gate bipolar transistor (RB-IGBT) or a simple IGBT. The present invention may also be applied to a MOSFET having a configuration in which a drain region of n⁺-type is used instead of the p⁺-type collector region 9 that is the IGBT in the transistor part 101 illustrated in FIG. 2.

The configurations disclosed in the first to fourth embodiments may be combined as appropriate within a range that does not contradict with the scope of the respective embodiments. As described above, the invention includes various embodiments of the present invention and the like not described herein. Therefore, the scope of the present invention is defined only by the technical features specifying the present invention, which are prescribed by claims, the words and terms in the claims shall be reasonably construed from the subject matters recited in the present specification.

1. A method of manufacturing a semiconductor device comprising:
forming a first trench from an upper surface side of a semiconductor substrate of a first conductivity-type;
burying the first trench with an insulated gate electrode structure;
forming a base region of a second conductivity-type at an upper part of the semiconductor substrate so as to be in contact with the first trench;
forming a first main electrode region of the first conductivity-type at an upper part of the base region so as to be in contact with the first trench;
forming a second trench by removing a part of the first main electrode region;
implanting first impurity ions of the first conductivity-type entirely into a side wall surface of the second trench from a diagonally upper side;
implanting second impurity ions of the second conductivity-type into a bottom surface of the second trench so as to form a contact region of the second conductivity-type at a bottom of the second trench; and
forming a second main electrode region of the second conductivity-type on a bottom surface side of the semiconductor substrate.

2. The method of manufacturing the semiconductor device of claim 1, wherein the implanting the first impurity ions is executed to include a corner defined by the bottom surface of the second trench and the side wall surface of the second trench.

3. The method of manufacturing the semiconductor device of claim 1, wherein the implanting the first impurity ions is executed to avoid a middle part of the bottom surface of the second trench.

4. The method of manufacturing the semiconductor device of claim 1, wherein an opening width of the second trench is greater than a width of the bottom surface of the second trench.

5. The method of manufacturing the semiconductor device of claim 1, wherein the implanting the first impurity ions is executed to implant the impurity ions into side wall surfaces on both sides of the second trench.

6. The method of manufacturing the semiconductor device of claim 1, wherein the implanting the first impurity ions is executed to implant the impurity ions into one of side wall surfaces of the second trench.

7. The method of manufacturing the semiconductor device of claim 1, wherein a dose of the first impurity ions to be implanted is 1% or greater and 10% or smaller of a dose of the second impurity ions to be implanted.

8. The method of manufacturing the semiconductor device of claim 1, wherein an acceleration energy upon the implanting the first impurity ions is higher than an acceleration energy upon the implanting the second impurity ions.

9. The method of manufacturing the semiconductor device of claim 1, wherein the first impurity ions are phosphorus, and the second impurity ions are boron.

10. The method of manufacturing the semiconductor device of claim 1, wherein:
the forming the second trench is executed to lead the bottom surface of the second trench to be located inside the first main electrode region; and
the forming the contact region is executed to lead the contact region to be in contact with the base region.

11. The method of manufacturing the semiconductor device of claim 1, wherein:
the forming the second trench is executed to lead the bottom surface of the second trench to be located inside the base region; and
the forming the contact region is executed to lead the contact region to be in contact with the base region.

12. The method of manufacturing the semiconductor device of claim 1, wherein the insulated gate electrode structure, the base region, the first main electrode region, and the second main electrode region implement an insulated gate bipolar transistor.
